(19) United States
(12) Patent Application Publication
(10) Pub. No.: US 2013/0001699 A1
(43) Pub. Date: Jan. 3, 2013

(54) TRENCH JUNCTION BARRIER SCHOTTKY STRUCTURE WITH ENHANCED CONTACT AREA INTEGRATED WITH A MOSFET

(75) Inventors: Sung-Shan Tai, Hsinchu City (TW); Po-Hsien Li, Tainan City (TW); Guo-Liang Yang, Hsinchu City (TW); Shian Hau Liao, Taichung City (TW)

(73) Assignee: SINOPOWER SEMICONDUCTOR, INC., TAIWAN (TW)

(21) Appl. No.: 13/171,475

(22) Filed: Jun. 29, 2011

(51) Int. Cl. H01L 27/06; H01L 21/283

(52) U.S. Cl. 257/368; 438/570; 257/E27.016; 257/E21.159

(57) ABSTRACT

An object of this invention is to provide a Schottky diode structure to increase the contact area at a Schottky junction between the Schottky Barrier metal and a semiconductor substrate. The larger contact area of the Schottky junction is, the lower of the forward voltage drop across the Schottky diode will be, thereby improving the performance and efficiency of the Schottky diode.

The present invention also discloses that a plurality of trenches with adjacent top mesas can be used to form a Schottky diode with even larger contact area, wherein the trenches are built using the isolation area between two cells of MOSFET with minimum extra overhead by shrinking the dimension of pitch between two trenches.

### FIELD OF THE INVENTION

The present invention relates to a MOSFET technology and, in particular, to a MOSFET with an integrated Schottky diode.

### BACKGROUND OF THE INVENTION

In a typical Pulse-Width-Modulation (PWM) circuit for power converters, a high side Metal Oxide Semiconductor Field-Effect Transistor (MOSFET) and a lower side MOSFET are used for rectifying purpose in order to generate an output voltage when used in a DC-DC convertor. In operating, the lower side (LS) MOSFET usually requires longer time to switch from off state to on state; and, during such time period, a body diode may turn on by a higher voltage at the drain than at the source electrode, which will cause power losses in the high side MOSFET by the current flowing from the drain electrode through the body diode to the high side MOSFET. Therefore, it is very important to prevent the body diode from turning on by using a Schottky diode in parallel with the body diode to eliminate the reverse recover loss of the body diode.

Schottky diode has little or no minority carrier injection in forward conduction, so that it can prevent the body diode to turn on so as to cut down the reverse recover loss of the body diode; it also reduces the forward conduction losses due to its lower forward voltage drop. Therefore, the Schottky diode can reduce power losses and improve power efficiency when it is connected in parallel with the body diode across the drain and the source electrodes of a MOSFET.

As power converter applications continue to ramp up towards higher voltage and faster switching speed; thus how to integrate a Schottky diode into a MOSFET device becomes an important task. An US patent, 2010/0258897, discloses a trench junction barrier Schottky diode which is built within a MOSFET device for achieving this goal. However, the trench junction barrier Schottky diode, disclosed in the US 2010/0258897, is built in the cell region of the MOSFET itself, which has limited shrinking capability for the future device in order to lower down the forward voltage drop efficiently, which is an important issue for some power applications.

Therefore, a need still exists to design a Schottky diode especially integrated with a MOSFET device to improve overall switching speed and to reduce the forward voltage drop even further for higher speed, higher power converter applications.

### SUMMARY

An object of this invention is to provide a Schottky diode structure to increase the contact area at a Schottky junction between a Schottky barrier metal and a semiconductor substrate. The larger contact area of the Schottky junction is, the lower of the forward voltage drop across the Schottky diode will be, thereby improving the performance and efficiency of the Schottky diode.

In one embodiment of this invention, a trench junction barrier Schottky structure with enhanced contact area between the Schottky Barrier metal and the semiconductor substrate is described, wherein at least one trench is built between two MOSFETs with top mesas adjacent to the trench, and a barrier metal is overlaid on the inner surface of the trench extending over the top mesas so that overall contact area at the Schottky junction can be increased.

Furthermore, in order to prevent the leakage current flowing between the two Schottky diodes on the two sidewalls of the trench through the region underneath the bottom of the trench, a second conductivity type is implanted with a predefined concentration into the region underneath the bottom of the trench.

The present invention also discloses that a plurality of trenches with adjacent top mesas can be used to form a Schottky diode with even larger contact area, wherein the trenches are built using the area between two cells of MOSFET with minimum overhead by shrinking the dimension of pitch between two trenches.

In another embodiment of this invention, a method to manufacture the trench junction barrier Schottky structure is described, wherein an insulating layer is formed over the substrate extending over the top mesas between the trenches. In addition, a mask can be used to remove the insulating layer over the top mesas or the insulating layer can be maintained on the top of the mesas without using the mask.

In yet another embodiment of this invention, a MOSFET integrated with a trench junction barrier Schottky structure is described, in which the Schottky structure is built across the source and drain electrodes of the MOSFET.

### BRIEF DESCRIPTION OF THE DRAWINGS

The foregoing aspects and many of the accompanying advantages of this invention will become more readily appreciated as the same becomes better understood by reference to the following detailed description when taken in conjunction with the accompanying drawings, wherein:

FIG. 1A is a cross sectional view of trench junction barrier Schottky structure in one embodiment.

FIG. 1B is another cross sectional view of FIG. 1.

FIG. 1C is a cross sectional view of trench junction barrier Schottky structure with a guarded region.

FIG. 1D is a flow chart for describing the manufacturing process for a Schottky diode in the FIG. 1C.

FIG. 2 is a cross sectional view of the Schottky diode integrated with a MOSFET.

FIG. 3 is a flow chart for describing the manufacturing process for a Schottky diode with a mask.

FIG. 4A to 4D are the cross sectional views for describing the manufacturing processes for a Schottky diode with a mask.

FIG. 5 is a flow chart for describing the manufacturing process for a Schottky diode without a mask.

FIG. 6A to 6D are the cross sectional views for describing the manufacturing processes for a Schottky diode integrated with a MOSFET without a mask.

### DETAIL DESCRIPTION OF THE INVENTION

The invention will now be described in greater detail with preferred embodiment and illustrations attached. Nevertheless, it should be recognized that the preferred embodiments of the invention are only for illustrating. Besides the preferred embodiments mentioned here, this present invention can be practiced in a wide range of other embodiments besides those explicitly described, and the scope of the present invention is expressly not limited expect as specified in the accompanying claims.

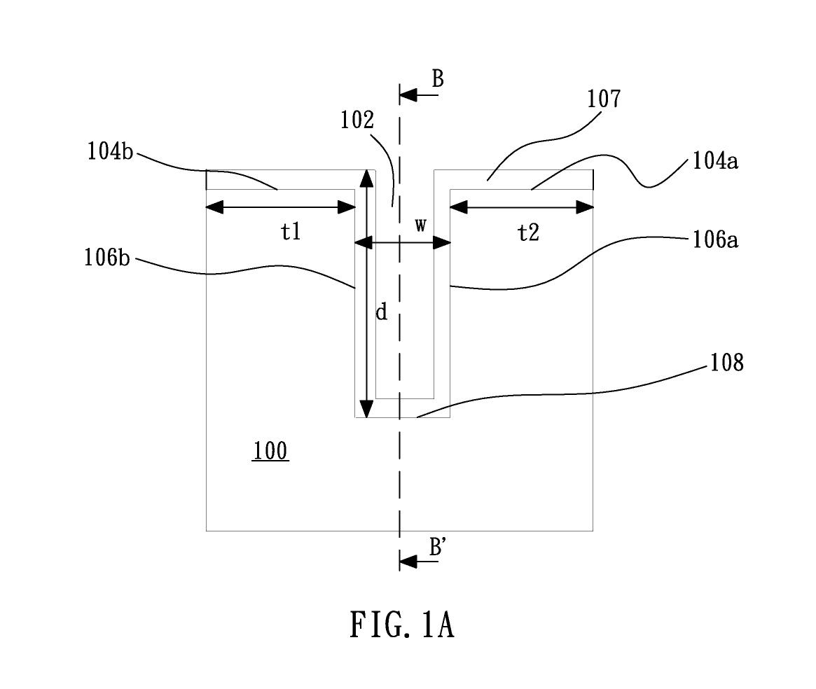

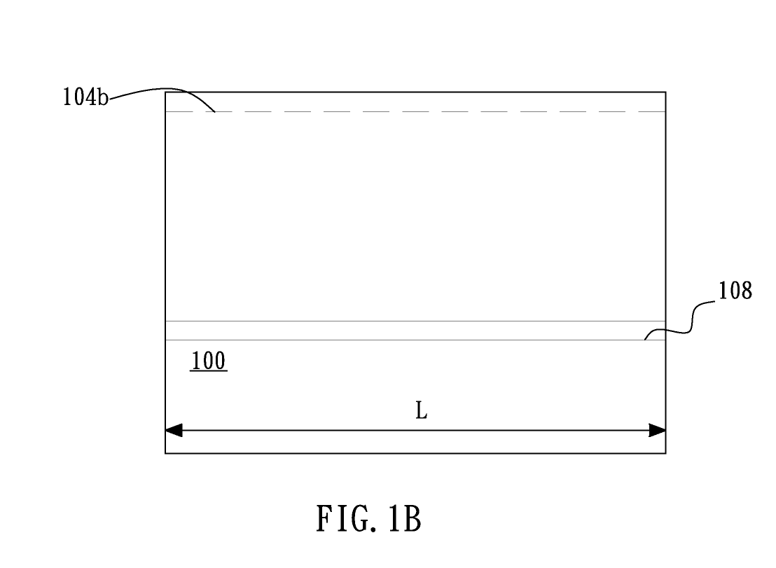

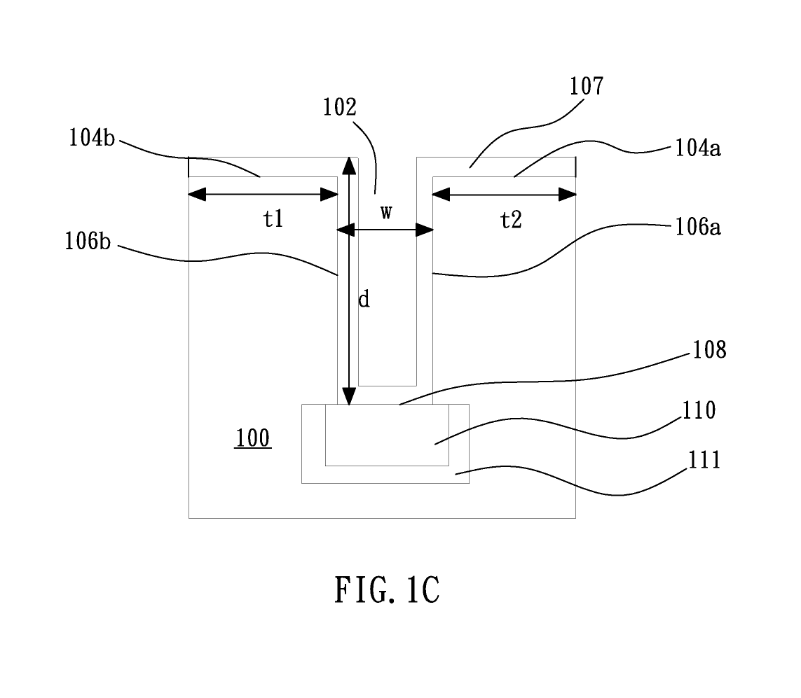

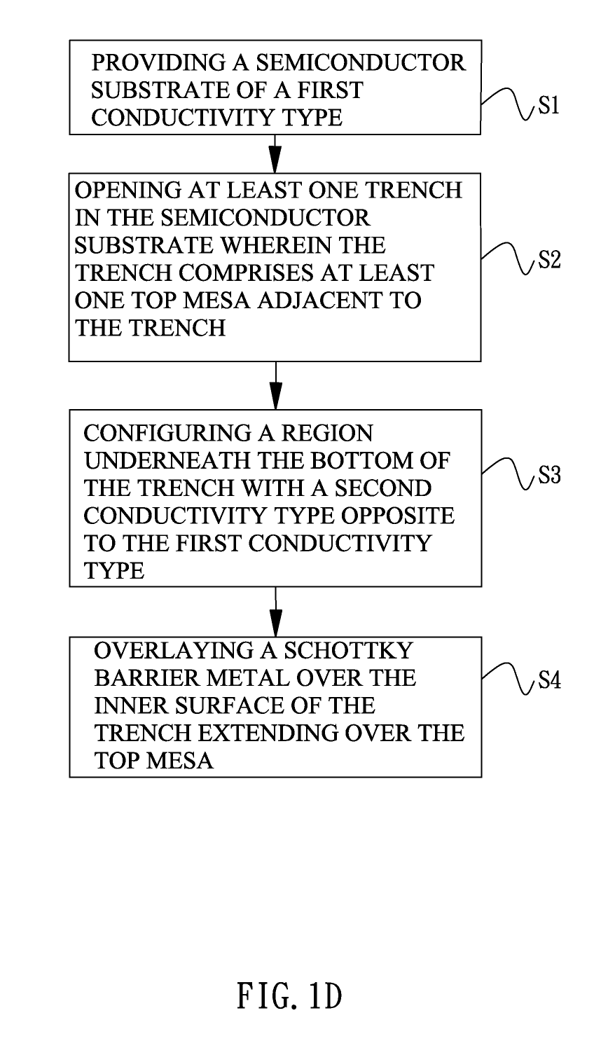

FIG. 1A illustrates a cross sectional view of a Schottky diode in accordance with one embodiment of the present invention. A trench 102 is opened in a semiconductor substrate 100 of a conductivity type, which includes a first sidewall 106a, a second sidewall 106b which is opposite to the first sidewall 106a, and a bottom mesa 108. On each side of the trench opening, there is a top mesa adjacent to the trench, for example, a first top mesa 104a is adjacent to the right-hand side of the trench 102 and a second top mesa 104b is adjacent to the left-hand side of the trench 102. The inner surfaces of the first sidewall 106a, the second sidewall 106b, and the bottom mesa 108 inside the trench are collectively called the inner surface of the trench 102.

In order to form a Schottky diode, a Schottky barrier metal 107 is overlaid over the inner surface of the trench extending over the first top mesa 104a and the second top mesa 104b, by which a plurality of Schottky junctions are formed at the first top mesa 104a, the second top mesa 104b, the first sidewall 106a, the second sidewall 106b and the bottom mesa 108.

The area of the Schottky barrier metal overlapping with the semiconductor substrate 100 defines the contact area of the Schottky structure at the junction, and the contact area will affect the barrier height of the Schottky junction, which in turn will affect the Schottky forward voltage drop.

The area of junction at the first top mesa 104a and the second top mesa 104b increases the contact area of the Schottky diode.

The total area of the junctions may express in following equation (1):

Area=(t1+2*d+t2+w)*L (1)

wherein t1 is the width of the second top mesa 104b and t2 is the width of the first top mesa 104a, w is the width of the trench 102, d is the depth of the trench 102 and L is length of the contact area for the first top mesa 104a, the second top 104b, the first sidewall 106a and the second 106b as shown in FIG. 1B, which shows the cross sectional view of dot line B-B′ in FIG. 1A.

The overlaid Schottky barrier metal over the inner surface of each sidewall forms a Schottky junction respectively, in order to ensure the two Schottky junctions formed on the two sidewalls are not contacted by the barrier metal itself inside the trench, the thickness of barrier metal 107 is less than the half width w of the trench 102 so that it can save rooms for the contact metal, which will be overlaid over the Schottky barrier metal latter on for creating a metal contact for electrical connection.

The Schottky barrier metal 107 includes, but is not limit to, Ti/TiN, Co/TiN, Pt/TiN, Mo/TiN, Ni/TiN and a combination thereof to form the Schottky junction for different Schottky barrier height.

In another embodiment, referring to FIG. 1C, a guarded region 110 underneath the bottom of the trench 108 is implanted with a p-type dopant before forming the barrier metal 107 as illustrated in FIG. 1A, which forms a depletion region 111 at the junction of the guarded region 110 and the substrate 100 which is n-type in this embodiment. The depletion region 111 prevents the leakage current flowing between the two Schottky diodes on the two sidewalls of the trench through the guarded region underneath the bottom of the trench. The depletion region contains the p type ionized atoms with negative charges which will push away the electrons flowing between the two Schottky diodes on the two sidewalls of the trench through the channel underneath the bottom of the trench. In this embodiment, with the p type guarded region underneath the bottom mesa 108, the surface of bottom mesa 108 does not form a junction of a Schottky diode, because the guarded region will block the electronics flowing through from the substrate to the barrier metal as well.

The pinch-off voltage across the PN junction to pinch off the conducting channel underneath the Schottky barrier metal to block all the electronics flowing through this region, which will effectively block all the leakage current flowing between the two sidewalls of the trench through the region underneath the bottom of the trench.

Please refer to FIG. 1D, which illustrates a process of a Schottky diode. The process comprises the steps as following:

Step S1: providing a semiconductor substrate of a first conductivity type;

Step S2: opening at least one trench in the semiconductor substrate wherein the trench comprises at least one top mesa adjacent to the trench;

Step S3: configuring a region underneath the bottom of the trench with a second conductivity type opposite to the first conductivity type;

Step S4: overlaying a Schottky barrier metal over the inner surface of the trench extending over the top mesa.

The step S1 provides a semiconductor substrate of n-type dopant.

The step S2 opens a trench in the semiconductor substrate by lithography process, and the portion adjacent to the opening of the trench on the substrate will be called top mesa.

The step S3 implants the region underneath the bottom of the trench with a p-type dopant; the detail of concentration of the p-type dopant has been described in the structure embodiment.

The step S4 overlays a Schottky barrier metal on the surface of the trench and the top mesa; and the detail has been described in the structure embodiment.

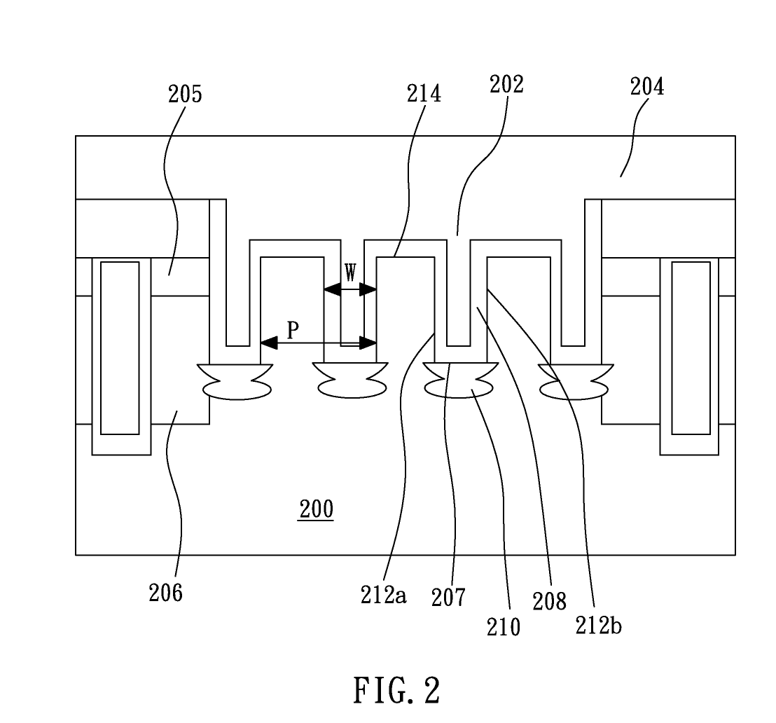

Please refer to FIG. 2, which illustrates a cross sectional view of a Schottky diode integrated with a MOSFET device in an n-type substrate 200 in accordance with another embodiment of the present invention.

The trench 202 include a first sidewall 212a, a second sidewall 212b which is opposite to the first sidewall 212a and a bottom mesa 207. The top mesa 214 is adjacent to the trench 202. The Schottky barrier metal 208 overlays the first sidewall 212a and the second sidewall 212b, the bottom mesa 207 and the top mesa 214, and then a contact metal 204 overlays the barrier metal 208 for making electrical connections to outside. A guarded region 210 is implanted with a p-type dopant underneath the bottom mesa 207 to block the leakage current between the first sidewall 212a and the second sidewall 212b underneath the bottom mesa 207.

Please continuously refer to FIG. 2; the contact area of the Schottky junctions increased by the top mesas can be expressed in following equation (4):

Area=(p−w)*L*n (4)

wherein p is the pitch between two adjacent trenches, w is the width of the trench 202, n is the number of the top mesas, and L is length of the contact area as illustrated in FIG. 1B

A contact metal 204 is deposited on barrier metal 208, which can be used for contact point for making electrical connection to the external signals. The contact metal 204 includes, but it is not limited to, AlCu, Tungsten/Al—Si, or a combination thereof.

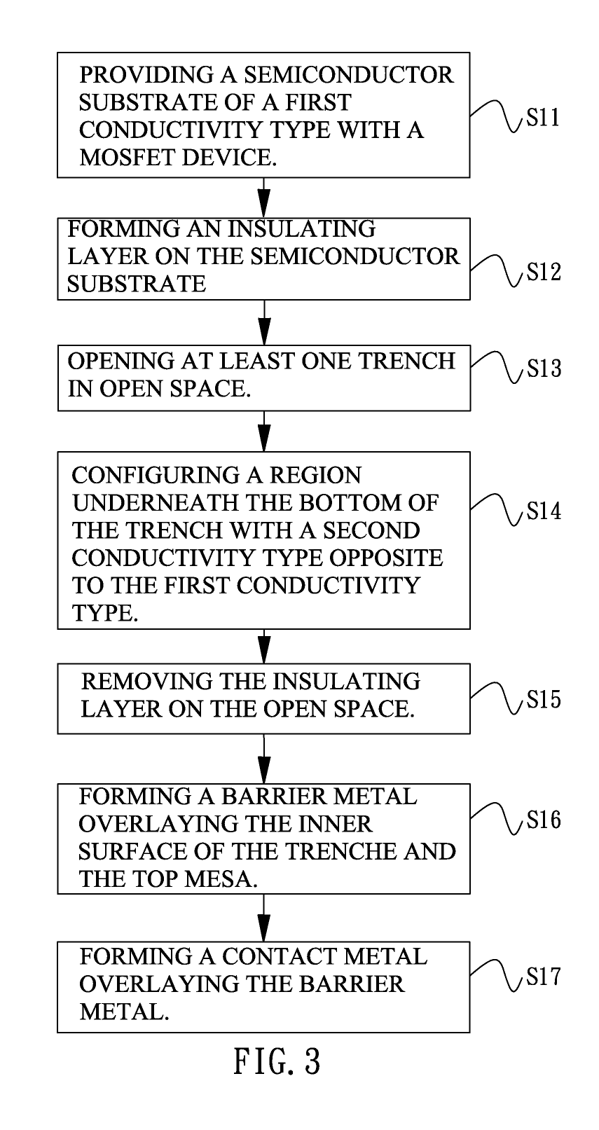

Please refer to FIG. 3, which illustrate a process of a Schottky diode integrated with a MOSFET with a mask. The process comprises the steps as following:

Step 11: providing a semiconductor substrate of a first conductivity type with a MOSFET device;

Step 12: forming an insulating layer on the semiconductor substrate;

Step 13: opening at least one trench in open space;

Step 14: configuring a region underneath the bottom of the trench with a second conductivity type opposite to the first conductivity type;

Step 15: removing the insulating layer in the open space;

Step 16: forming a barrier metal overlaying the inner surface of the trench and the top mesa;

Step 17: forming a contact metal overlaying the barrier metal.

The step S11 provides a semiconductor substrate of n-type dopant with a trench gate MOSFET device, wherein the trench gate MOSFET device has source electrode, gate electrode and body well in a cell region in the semiconductor substrate. The region between the cell regions is called open space.

The step S12 deposits an insulating layer on the semiconductor substrate, and the insulating layer includes, but is not limited, low temperature oxide (LTO) or Borphosphorsilikat glass (BPSG).

The step S13 opens a trench in the open space by a lithography process in one embodiment.

The step S14 implants a region underneath the bottom of the trench with a p-type dopant by an implementing process, and the p-type dopant includes, but is not limited to, Boron or BF2.

The step S15 removes the insulating layer in the open space by a lithograph process with a mask.

The step S16 forms a barrier metal overlaying the inner surface of the trench and the top mesa.

The step S17 forms a contact metal on the device, it fills the opening of the trench and overlays the barrier metal on the inner surface of the trench. The contact metal can be, but it is not limited to, AlCu, W/AlCu or a combination thereof.

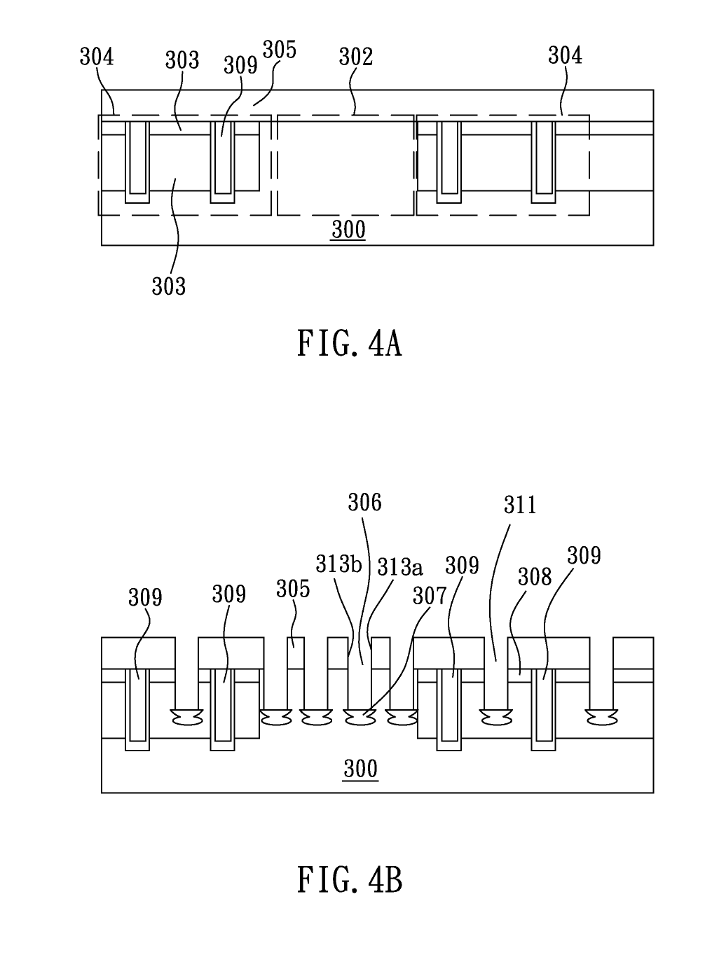

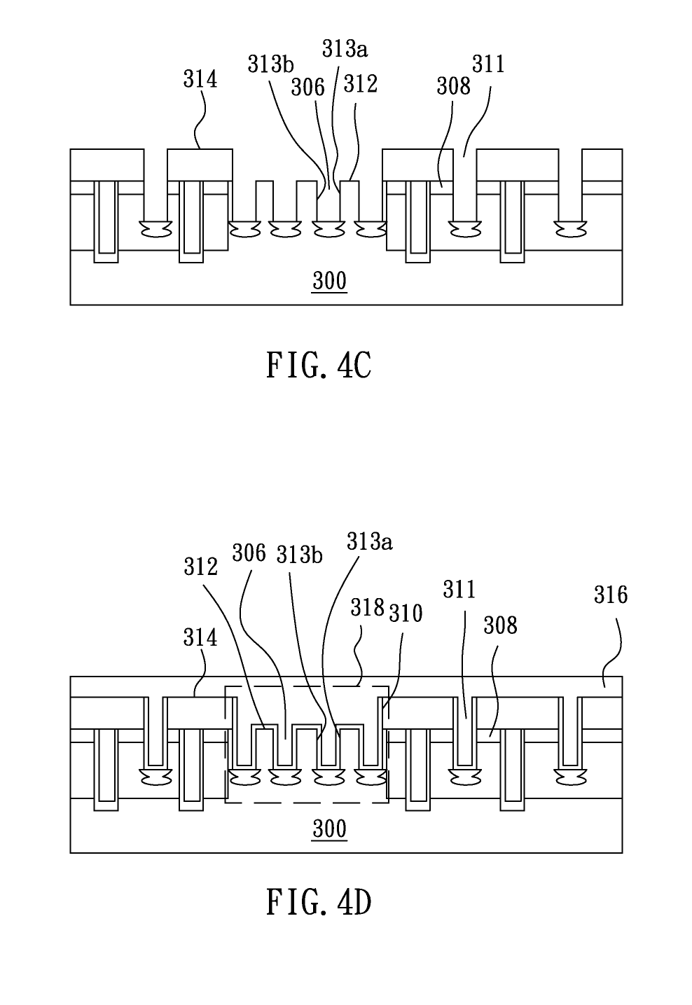

Please refer to FIG. 4A, which illustrate a Schottky structure integrated with a MOSFET in accordance with one embodiment of this invention. A trench gate MOSFET device includes an open space 302 and a cell region 304 in an n-type semiconductor substrate 300, wherein the cell region 304 includes source electrodes 308, gate electrodes 309 and a body well 303; and the open space 302 is a region which does not include source electrode 308, gate electrodes 309 and body well 303. An insulating layer 305 is deposited on the MOSFET, which includes, but is not limited, low temperature oxide (LTO) or Borphosphorsilicat glass (BPSG).

Please refer to FIG. 4B, a plurality of trenches 306 in the open space 302, which includes a first sidewall 313a, a second sidewall 313b opposite to the first sidewall 313a, and a contact hole 311 adjacent to the gate electrode 309 in cell region 304 are formed. Then, the guarded region 307 of p-type dopant underneath the bottom of the trenches 306 is formed by an ion implanting process. The guarded region 307 of p-type dopant can be, but is not limited to, Boron or BF2.

Referring to FIG. 4C, the insulating layer 305 is removed in the open space 302 to expose the top mesa 312 with the top mesa 314 in the cell region is still covered by the insulating layer 305.

Referring to FIG. 4D, a barrier metal 310 is overlaid on the inner surface of the trenches 306, extending over the top mesa 312; as a result, the Schottky junctions are created on the first sidewall 313a, the second sidewall 313b and the top mesa 312. Then, the contact metal 316 is deposited on the barrier metal 310 and the top mesa 314. The contact metal 316 can be, but it is not limited to, AlCu, W/AlCu or a combination thereof.

In one embodiment, the barrier metal 310 and contact metal 316 can be deposited at the same step.

The contact hole 311 electrically connects the source electrode 308 and barrier metal 310. The thickness of the barrier metal 310 is less than the half width of each trench.

Consequently, the source electrode 308 of the MOSFETs and the Schottky diode device 318 are electrically connected by the contact hole 311; and the drain electrode is connected through the substrate 300.

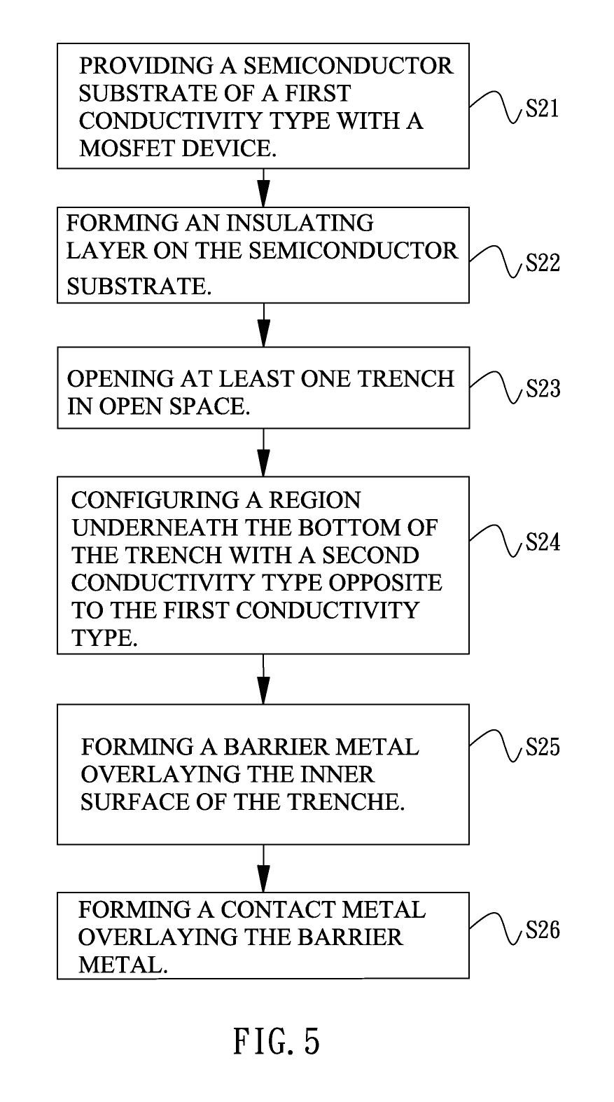

Please refer to FIG. 5, which illustrate a process of a Schottky diode integrated with a MOSFET without a mask. The steps of S21, S22, S23, S24 and S26 are the same as the steps of S11, S12, S13, S14 and S17 respectively illustrated in FIG. 3.

The step S25 forms a barrier metal without removing the insulating layer in the open space, and the barrier metal is overlaid on the inner surface of the trench and the insulating layer, and then the barrier metal on the insulating layer is removed by CMP or etching process.

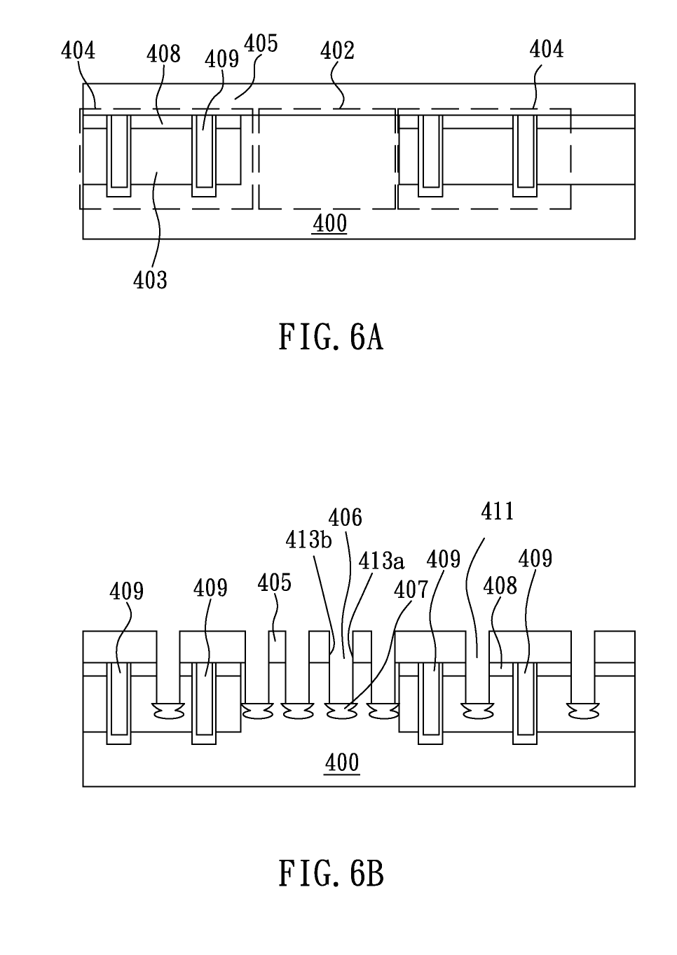

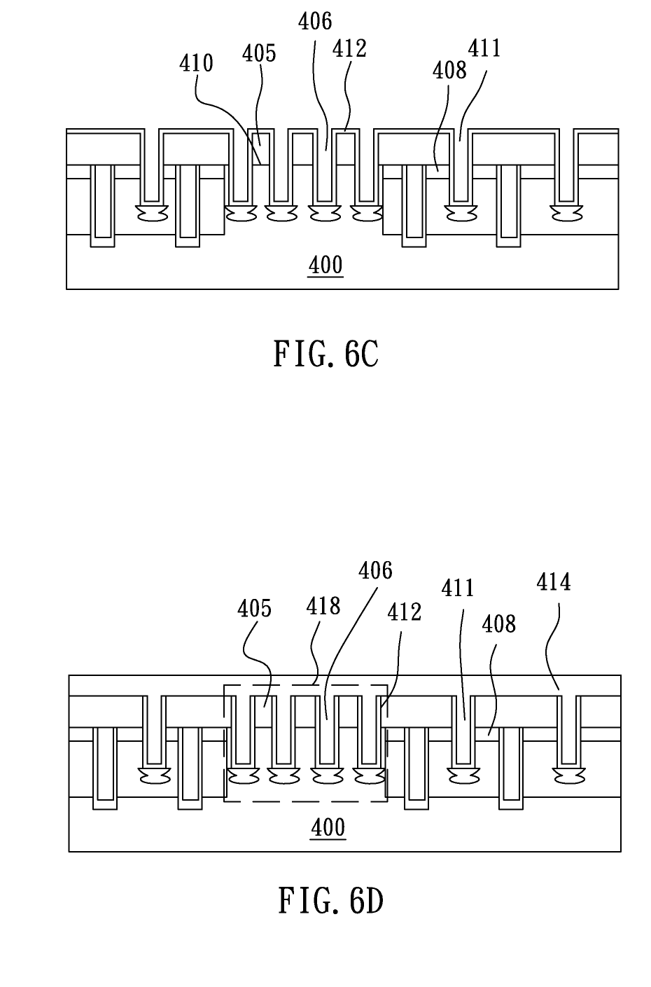

Referring to FIG. 6A, a trench gate MOSFET device includes an open space 402 and cell region 404 formed in a n-type semiconductor substrate 400, wherein the cell region 404 includes source electrodes 408, gate electrodes 409 and body well 403. The open space 402 is a region between two cell regions. An insulating layer 405 is deposited on the MOSFET, which can be, but not limited to, LTO or BPSG. The process is not limited to the trench gate MOSFET but can be any other type of MOSFET as well.

Please refer to FIG. 6B, an insulating layer 405 is deposited on the MOSFET; the insulating layer 405 includes, but is not limited, LTO or BPSG. And then, a plurality of trenches 406 are formed in the open space 402, which includes a first sidewall 413a, a second sidewall 413b which is opposite to the first sidewall 413a, and a plurality of contact holes 411 adjacent to the gate electrode 409 in the cell region. Then, the guarded region 407 of p-type dopant underneath the bottom of the trench 406 is formed by an ion implanting process. The guarded region 407 of p-type dopant can be, but is not limited to, Boron or BF2.

Referring to FIG. 6C, the Schottky barrier metal 412 is formed overlaying the inner surface of the trenches 406 and insulating layer 405, wherein the insulating layer 405 is between the top mesa 410 and barrier metal 412. The contact hole 411 electrically connects the source electrode 408 and barrier metal 410.

Referring to FIG. 6D, removing the barrier metal 412 on the insulating layer 405 by CMP process or etching process. Then, a contact metal 414 is formed over the barrier metal, which fills the opening of the trench and connects the Schottky diode and source electrode 408.

In one embodiment, the barrier metal 412 and contact metal 414 can be deposited at the same step.

Consequently, the source electrode 408 of the MOSFETs and the Schottky diode device 418 are electrically connected; and the drain electrode is connected through the substrate 400.

As described above, in the preferred embodiment, the conductivity type of the semiconductor substrate 100, 200, 300 and 400 is n-type, and the conductivity type of the guarded region 110, 210, 307 and 407 is p-type. Alternatively, the conductivity type of the semiconductor substrate 100, 200, 300 and 400 is p-type, and the conductivity type of the guarded region 110, 210, 307 and 407 is n-type.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

1. A MOSFET integrated with a trench Junction Barrier Schottky (TJBS), comprising:
a MOSFET comprising a source electrode, which is formed in a semiconductor substrate of a first conductivity type;
a trench Junction Barrier Schottky (TJBS) structure formed in the semiconductor substrate of the first conductivity type adjacent to the MOSFET, comprising:
a first trench opened in the semiconductor substrate of the first conductivity type;
a first top mesa adjacent to the first trench;
a Schottky barrier metal overlaying the inner surface of the first trench and extending over the first top mesa; and
a contact metal overlaying the Schottky barrier metal, wherein the contact metal is electrically connected to the source electrode of the MOSFET.

2. A MOSFET integrated with a trench Junction Barrier Schottky (TJBS) according to claim 1, wherein the MOSFET further comprises a trench opening in the source region of the MOSFET in the semiconductor substrate, wherein the trench opening is electrically connected to the source electrode by the contact metal.

3. A MOSFET integrated with a trench Junction Barrier Schottky (TJBS) according to claim 1, wherein a region underneath the bottom of the first trench in the trench Junction Barrier Schottky (TJBS) structure is configured with an impurity of a second conductivity type opposite to the first conductivity type.

4. A MOSFET integrated with a trench Junction Barrier Schottky (TJBS) according to claim 1, wherein the trench Junction Barrier Schottky (TJBS) structure further comprises a second trench adjacent to the first top mesa, wherein the Schottky barrier metal overlaying is extending over the inner surface of the second trench.

5. A MOSFET integrated with a trench Junction Barrier Schottky (TJBS) according to claim 4, wherein the trench Junction Barrier Schottky (TJBS) structure further comprises a second top mesa adjacent to the second trench, wherein the Schottky barrier metal overlaying is extending over the second top mesa.

6. A MOSFET integrated with a trench Junction Barrier Schottky (TJBS) according to claim 3, wherein the first conductivity type is n type and the second conductivity type is p type.

7. A MOSFET integrated with a trench Junction Barrier Schottky (TJBS) according to claim 3, wherein the first conductivity type is p type and the second conductivity type is n type.

8. A MOSFET integrated with a trench Junction Barrier Schottky (TJBS) according to claim 3, wherein the second conductivity type in the region underneath the bottom of the first trench is configured according to a pre-defined concentration to block the leakage current flowing between the two sidewalls of the first trench through the region underneath the bottom of the first trench.

9. (canceled)

10. (canceled)

11. A method for manufacturing a MOSFET integrated with a trench Junction Barrier Schottky (TJBS), the method comprising the steps of:
a. forming a MOSFET comprising a source electrode in a semiconductor substrate of a first conductivity type;
b. forming a trench Junction Barrier Schottky (TJBS) in the semiconductor substrate adjacent to the MOSFET, comprising the steps of:
b1. opening a trench in the semiconductor substrate wherein the trench comprises at least one top mesa adjacent to the trench;
b2. overlaying a Schottky barrier metal over the inner surface of the trench and extending over said at least one top mesa; and
c. forming a contact metal overlaying the Schottky barrier metal, wherein the contact metal is electrically connected to the source electrode of the MOSFET.

12. A method for manufacturing a MOSFET integrated with a trench Junction Barrier Schottky (TJBS) according to claim 11, wherein the step c further comprises opening a trench in the source region of the MOSFET in the semiconductor substrate, wherein the trench in the source region is electrically connected to the source electrode by the contact metal.

13. A method for manufacturing a MOSFET integrated with a trench Junction Barrier Schottky (TJBS) according to claim 11, wherein the step b1 further comprises a sub-step of:
b11. configuring a region underneath the bottom of the trench with a second conductivity type opposite to the first conductivity type.

14. A method for manufacturing a MOSFET integrated with a trench Junction Barrier Schottky (TJBS) according to claim 13, wherein configuring the region underneath the bottom of the trench with a second conductivity type opposite to the first conductivity type is by implanting process.

15. (canceled)

16. (canceled)

17. The method for manufacturing a MOSFET integrated with a trench Junction Barrier Schottky (TJBS), further comprising the steps of:
d. implanting an impurity of a second conductivity type opposite to the first conductivity type in a region underneath the bottom of the trench.
